(19) United States
(12) Patent Application Publication
(10) Pub. No.: US 2025/0096676 A1
(43) Pub. Date: Mar. 20, 2025

(54) CHARGE PUMP SYSTEM AND OPERATION METHOD THEREOF

(71) Applicant: SAMSUNG ELECTRO-MECHANICS CO., LTD., Suwon-si (KR)

(72) Inventors: Shinichi IIZUKA, Suwon-si (KR); Hyejin LEE, Suwon-si (KR); Jeonghoon KIM, Suwon-si (KR); Youngwong JANG, Suwon-si (KR)

(73) Assignee: SAMSUNG ELECTRO-MECHANICS CO., LTD., Suwon-si (KR)

(21) Appl. No.: 18/583,232

(22) Filed: Feb. 21, 2024

(30) Foreign Application Priority Data
Sep. 20, 2023 (KR) 10-2023-0125742

(51) Int. Cl. H02M 3/07; H03K 5/24

(52) U.S. Cl. CPC H02M 3/07; H03K 5/249

(57) ABSTRACT

A charge pump system and method of operating the same are provided. The charge pump system includes a charge pump circuit configured to convert an input voltage to an output voltage; a comparator configured to compare the output voltage with a reference voltage, and output a control signal that corresponds to a result of the comparing; a driver configured to generate the input voltage in response to an operation clock signal, and provide the generated input voltage to the charge pump circuit; and a selector configured to provide one of a first clock signal of a first frequency and a second clock signal of a second frequency lower than the first frequency as the operation clock signal to the driver, based on the control signal.

### CROSS-REFERENCE TO RELATED APPLICATIONS

This application claims the benefit under 35 USC § 119(a) of Korean Patent Application No. 10-2023-0125742 filed on Sep. 20, 2023, in the Korean Intellectual Property Office, the entire disclosure of which is incorporated herein by reference for all purposes.

### BACKGROUND

### 1. Field

This following description relates to a charge pump system and operation method thereof.

### 2. Description of Related Art

The charge pump system may repeat charging and discharging operations at every clock to gradually increase or decrease the voltage. Accordingly, startup time may be delayed depending on the clock frequency.

Typically, in order to speed up the startup time, there is a way to increase the charging and discharging amount by increasing the clock frequency or increasing the capacitance of the pumping capacitor. However, if the clock frequency is increased, the harmonic characteristics worsen, and if the capacitance of the pumping capacitor increases, the possibility of clock noise generation may be increased and the size of the integrated circuit may be increased.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a charge pump system includes a charge pump circuit configured to convert an input voltage to an output voltage; a comparator configured to compare the output voltage with a reference voltage, and output a control signal that corresponds to a result of the comparing; a driver configured to generate the input voltage in response to an operation clock signal, and provide the generated input voltage to the charge pump circuit; and a selector configured to provide one of a first clock signal of a first frequency and a second clock signal of a second frequency lower than the first frequency as the operation clock signal to the driver, based on the control signal.

The charge pump system may include a first oscillator configured to generate the first clock signal and provide the generated first clock signal to the selector; and a second oscillator configured to generate the second clock signal and provide the generated second clock signal to the selector.

The second oscillator may not operate when the first oscillator operates, based on the control signal.

The input voltage may have a first voltage level and a second voltage level in response to the operation clock signal.

The selector may include a switch which has a first end that is connected to one of the first oscillator and the second oscillator based on the control signal, and a second end that is connected to the driver.

The output voltage may have a positive voltage, the comparator is configured to output a control signal having a first level when the output voltage is lower than the reference voltage, and output a control signal having a second level when the output voltage is greater than or equal to the reference voltage, and the selector may be configured to provide a clock signal of the first frequency to the driver based on the control signal of the first level.

The output voltage may be a negative voltage, the comparator may be configured to output a control signal having a first level when the output voltage is greater than the reference voltage, and output a control signal having a second level when the output voltage is less than or equal to the reference voltage, and the selector may be configured to provide a clock signal of the first frequency to the driver based on the control signal of the first level.

In a general aspect, a charge pump circuit operation method includes generating a first clock signal of a first frequency; generating a second clock signal of a second frequency lower than the first frequency; comparing an output voltage of the charge pump circuit with a reference voltage; generating a control signal based on a result of the comparing; selecting one of the first clock signal and the second clock signal in response to the control signal; generating an input voltage of the charge pump circuit based on the selected clock signal; and providing the generated input voltage to the charge pump circuit.

The input voltage may have a first voltage level and a second voltage level in response to the selected clock signal.

The output voltage may be a positive voltage, the selecting of the one of the first clock signal and the second clock signal may include selecting the first clock signal when the output voltage is lower than the reference voltage; and selecting the second clock signal when the output voltage is greater than or equal to the reference voltage.

The output voltage may be a negative voltage, the selecting of the one of the first clock signal and the second clock signal may include selecting the first clock signal when the output voltage is greater than the reference voltage; and selecting the second clock signal when the output voltage is less than or equal to the reference voltage.

Other features and aspects will be apparent from the following detailed description, the drawings, and the claims.

### BRIEF DESCRIPTION OF DRAWINGS

FIG. 1 illustrates an example charge pump system, in accordance with one or more embodiments.

FIG. 2 illustrates an example of the charge pump circuit shown in FIG. 1.

FIG. 3 illustrates another example of the charge pump circuit shown in FIG. 1.

FIG. 4 illustrates another example of the charge pump circuit shown in FIG. 1.

FIG. 5 illustrates an example of an inverter shown in FIG. 4.

FIG. 6 illustrates the operating state of the charge pump circuit shown in FIG. 5 in the first operation section.

FIG. 7 illustrates the operating state of the charge pump circuit shown in FIG. 5 in a second operation section.

FIG. 8 illustrates another example of the charge pump circuit shown in FIG. 1.

FIG. 9 illustrates the operating state of the charge pump circuit shown in FIG. 8 in the first operation section.

FIG. 10 illustrates the operating state of the charge pump circuit shown in FIG. 8 in a second operation section.

FIG. 11 illustrates an example clock signal used in an example charge pump system, in accordance with one or more embodiments.

FIG. 12 is a graph showing the effect of an example charge pump system, in accordance with one or more embodiments.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

Throughout the specification, an RF signal includes Wi-Fi (IEEE 802.11 family, etc.), WiMAX (IEEE 802.16 family, etc.), IEEE 802.20, long term evolution (LTE), Evolution-Data Optimized (Ev-DO), high-speed packet access plus (HSPA+), high-speed downlink packet access plus (HSDPA+), high-speed uplink packet access plus (HSUPA+), Enhanced Data GSM Evolution (EDGE), Global System for Mobile communication (GSM), Global Positioning System (GPS), General Packet Radio Service (GPRS), Code Division Multiple Access (CDMA), Time Division Multiple Access (TDMA), digital enhanced cordless communication (DECT), Bluetooth, third generation (3G), fourth generation (4G), fifth generation (5G), and any other wireless and wired protocols designated thereafter, but is not limited thereto.

One or more examples may provide a charge pump system and an operation method thereof that quickly generates an output voltage.

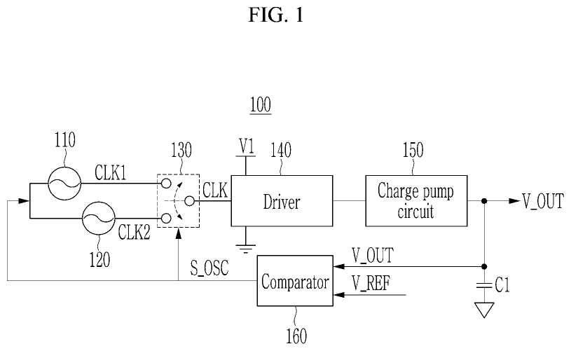

FIG. 1 illustrates an example charge pump system, in accordance with one or more embodiments.

Referring to FIG. 1, the charge pump system 100 may include an oscillator 110, an oscillator 120, a selector 130, a driver 140, a charge pump circuit 150, and a comparator 160. The charge pump system 100 may further include an output capacitor C1. Hereinafter, for convenience of explanation, the two oscillators 110 and 120 will be referred to as a first oscillator 110 and a second oscillator 120, respectively.

The first oscillator 110 may provide a clock signal CLK1 of a high frequency.

The second oscillator 120 may provide a clock signal CLK2 of a low frequency. The second oscillator 120 may provide a clock signal CLK2 with a frequency lower than the frequency of the clock signal CLK1 provided by the first oscillator 110.

The first oscillator 110 and the second oscillator 120 may respectively determine operating states according to the control signal S_OSC output from the comparator 160. The first oscillator 110 and the second oscillator 120 may have complementary operating states. For example, when the control signal S_OSC has a high level and a low level, if the operation state of the first oscillator 110 may be an active state at the high level, the operation state of the second oscillator 120 may be an inactive state at the high level.

The selector 130 may select a clock signal output from the first oscillator 110 or the second oscillator 120 according to the control signal S_OSC output from the comparator 160, and may provide the selected clock signal to the driver 140 as a clock signal CLK. In an example, the selector 130 may be implemented as a switch. One end of the switch may be connected to the first oscillator 110 or the second oscillator 120, and the other end of the switch may be connected to the driver 140. One end of the switch may be connected to the first oscillator 110 or the second oscillator 120 according to the control signal S_OSC output from the comparator 160.

The driver 140 may output a power supply voltage V1 or 0V to the charge pump circuit 150 according to the input clock signal CLK. For example, the driver 140 may output the power supply voltage V1 during a period in which the clock signal CLK has a high level, and output 0V during a period in which the clock signal CLK has a low level.

The charge pump circuit 150 may receive a voltage output from the driver 140 and generate an output voltage V_OUT having a different voltage level from the input voltage. The charge pump circuit 150 may generate an output voltage V_OUT having a voltage level higher than, or lower than, the input voltage.

The output capacitor C1 can stabilize the output voltage V_OUT of the charge pump circuit 150.

The comparator 160 may compare the output voltage V_OUT of the charge pump circuit 150 with a reference voltage V_REF and output a control signal S_OSC having a high level or a low level according to the comparison result.

As an example, when the charge pump system 100 provides an output voltage V_OUT having a positive voltage, the comparator 160 may control the signal S_OSC having the high level when the output voltage V_OUT of the charge pump circuit 150 is less than the reference voltage V_REF. The first oscillator 110 may be activated by the control signal S_OSC having a high level, and the selector 130 may provide the clock signal CLK1 provided by the first oscillator 110 to the driver 140 as the clock signal CLK. Additionally, the comparator 160 may output the control signal S_OSC having the low level when the output voltage V_OUT of the charge pump circuit 150 is greater than or equal to the reference voltage V_REF. The second oscillator 120 may be activated by the control signal S_OSC having the low level, and the selector 130 may provide the clock signal CLK2 provided by the first oscillator 120 to the driver 140 as the clock signal CLK.

In an example, when the charge pump system 100 provides an output voltage V_OUT having a negative voltage, the comparator 160 may control the signal S_OSC having a high level when the output voltage V_OUT of the charge pump circuit 150 is greater than or equal to the reference voltage V_REF. The first oscillator 110 may be activated by the control signal S_OSC having a high level, and the selector 130 may provide the clock signal CLK1 provided by the first oscillator 110 to the driver 140 as the clock signal CLK. The comparator 160 may output a control signal S_OSC having a low level when the output voltage V_OUT of the charge pump circuit 150 is less than the reference voltage V_REF. Additionally, the second oscillator 120 may be activated by the control signal S_OSC having the low level, and the selector 130 may provide the clock signal CLK2 provided by the first oscillator 120 to the driver 140 as the clock signal CLK.

When the charge pump circuit 150 operates according to the clock signal of a high frequency, the output voltage V_OUT may quickly reach a target voltage. Additionally, when the charge pump circuit 150 operates according to the clock signal of a low frequency, the time for the output voltage V_OUT to reach the target voltage is delayed, but degradation of harmonic characteristics can be reduced.

The charge pump system 100, according to the embodiment, may perform a charge pump operation according to the clock signal CKL1 of the high frequency when the output voltage V_OUT does not reach the reference voltage V_REF. Accordingly, the output voltage V_OUT may quickly reach the target voltage during initial startup. Additionally, the charge pump system 100 may perform a charge pump operation according to the clock signal CKL2 of the low frequency after the output voltage V_OUT reaches the reference voltage V_REF. Accordingly, it is possible to prevent deterioration of harmonic characteristics.

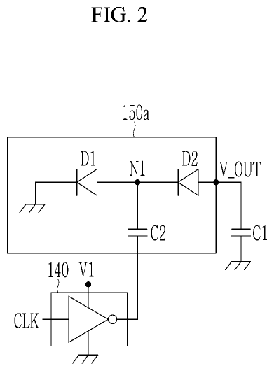

FIG. 2 illustrates an example of the charge pump circuit shown in FIG. 1.

Referring to FIG. 2, the charge pump circuit 150a may include a diode D1, a diode D2, and a pumping capacitor C2.

A cathode of diode D1 may be connected to a ground, and an anode of diode D1 may be connected to node N1.

A cathode of diode D2 may be connected to node N1, and an anode of diode D2 may be connected to the output capacitor C1.

One end of the pumping capacitor C2 may be connected to an output terminal of the driver 140, and the other end of the pumping capacitor C2 may be connected to the node N1.

This charge pump circuit 150a may generate an output voltage V_OUT from an input voltage that repeats the power supply voltage V1 and the ground voltage according to the clock signal CLK.

Specifically, when the power supply voltage V1 is input to the pumping capacitor C2 according to the clock signal CLK, a current path formed in the direction of the output capacitor C1, diode D2, diode D1, and ground may be formed, the pumping capacitor C2 may be charged with the power supply voltage V1.

Next, when the ground voltage is input to the pumping capacitor C2 according to the clock signal CLK, one end of the capacitor C2 is connected to ground, so the voltage of the other end of the pumping capacitor C2, that is, the node N1 becomes −V1, and the output voltage V_OUT, which is −V1, may be output through the current path of the output capacitor C1, diode D2, pumping capacitor C2, and ground.

This operation may be repeated according to the clock signal CLK, and accordingly, the charge pump system 100 may output the output voltage V_OUT having −V1, which is a substantially negative voltage.

The clock signal CLK may be a clock signal CLK1 of the first oscillator 110 or a clock signal CLK2 of the second oscillator 120 depending on the voltage level of the control signal S_OSC.

According to one embodiment, when the output voltage V_OUT is less than the reference voltage V_REF, the clock signal CLK may be a clock signal of the first oscillator 110. When the output voltage V_OUT is greater than or equal to the reference voltage V_REF, the clock signal CLK may be a clock signal of the second oscillator 120.

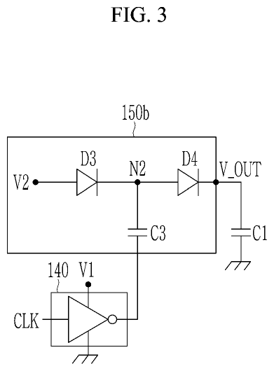

FIG. 3 is a diagram showing another example of the charge pump circuit shown in FIG. 1.

Referring to FIG. 3, the charge pump circuit 150b may include a diode D3, a diode D4, and a pumping capacitor C3.

An anode of diode D3 may be connected to the power supply voltage V2, and a cathode of diode D3 may be connected to node N2.

An anode of diode D4 may be connected to node N2, and a cathode of diode D4 may be connected to the output capacitor C1.

One end of the pumping capacitor C3 may be connected to the output terminal of the driver 140, and the other end of the pumping capacitor C3 may be connected to the node N2.

This charge pump circuit 150b may generate an output voltage V_OUT from an input voltage that repeats the power supply voltage V1 and the ground voltage according to the clock signal CLK.

Specifically, when the ground voltage is input to the pumping capacitor C3 according to the clock signal CLK, one end of the pumping capacitor C3 is connected to ground, so the pumping capacitor C3 may be charged to the voltage V2 through the current path of the diode D3, pumping capacitor C3, and ground. Additionally, the output capacitor C1 may also be charged through the current path of the diode D3, diode D4, and the output capacitor C1.

Next, when the power supply voltage V1 is input to the pumping capacitor C3 according to the clock signal CLK, the power supply voltage V1 may be supplied to one end of the capacitor C3. Thus, the voltage of the other end of the pumping capacitor C3, that is, the node V2 may become (V2+V1), and the output voltage V_OUT of (V2+V1) may be output through the current path of the pumping capacitor C3, diode D4, and output capacitor C1.

In an example, when the ground voltage is input to the pumping capacitor C3 according to the clock signal CLK, the voltage at the node N2 may become V2, and the reverse current may be blocked by the diode D4, so the output voltage V_OUT may be maintained the voltage (V2+V1).

This operation may be repeated according to the clock signal CLK, and through this operation, the charge pump system 100 may output the output voltage V_OUT of (V2+V1), which is a positive voltage.

In an example, the clock signal CLK may be a clock signal CLK1 of the first oscillator 110 or a clock signal CLK2 of the second oscillator 120 depending on the voltage level of the control signal S_OSC.

According to one embodiment, when the output voltage V_OUT is less than the reference voltage V_REF, the clock signal CLK may be a clock signal of the first oscillator 110. When the output voltage V_OUT is greater than or equal to the reference voltage V_REF, the clock signal CLK may be a clock signal of the second oscillator 120.

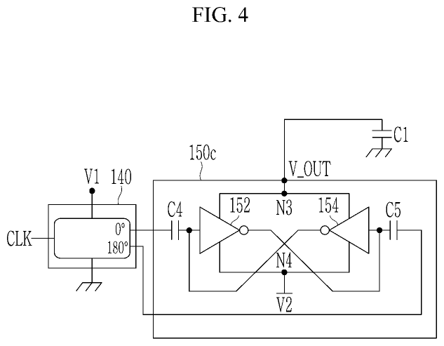

FIG. 4 is a diagram showing another example of the charge pump circuit shown in FIG. 1.

Referring to FIG. 4, the charge pump circuit 150c may include a pumping capacitor C4, a pumping capacitor C5, an inverter 152, and an inverter 154.

The driver 140 may have an input terminal, a non-inverting output terminal, and an inverting output terminal. The clock signal CLK may be input to the input terminal. The non-inverting output terminal may output the voltage selected according to the clock signal CLK. For example, the non-inverting output terminal may output a voltage V1 when the clock signal CLK has a high level and output 0V when the clock signal CLK has a low level. The inverting output terminal may output the phase-inverted voltage according to the clock signal CLK. For example, the inverting output terminal may output 0V when the clock signal CLK has a high level, and may output a voltage V1 when the clock signal CLK has a low level.

One end of the pumping capacitor C4 may be connected to the non-inverting output terminal of the driver 140, and the other end of the pumping capacitor C4 may be connected to an input terminal of the inverter 152.

One end of the pumping capacitor C5 may be connected to the inverting output terminal of the driver 140, and the other end of the pumping capacitor C5 may be connected to an input terminal of the inverter 154.

The inverter 152 may have an input terminal, an output terminal, a first power terminal, and a second power terminal. The output terminal of the inverter 152 may be connected to the input terminal of the inverter 154. The first power terminal of the inverter 152 may be connected to a node N3, and the second power terminal of the inverter 152 may be connected to a node N4.

The inverter 154 may have an input terminal, an output terminal, a first power terminal, and a second power terminal. The output terminal of the inverter 154 may be connected to the input terminal of the inverter 152. The first power terminal of the inverter 154 may be connected to the node N3, and the second power terminal of the inverter 154 may be connected to the node N4.

The node N3 may be connected to the output capacitor C1, and the node N4 may be connected to a power supply supplying voltage V2. The voltage of the node N3 may be the output voltage V_OUT of the charge pump circuit 150c.

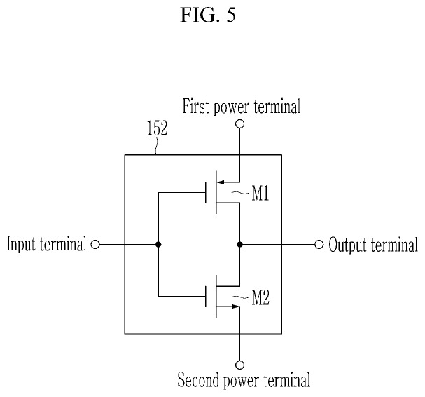

FIG. 5 is a diagram showing an example of an inverter shown in FIG. 4.

As shown in FIG. 5, in an example, the inverter 152 may be implemented as a combination of a p-type transistor M1 and an n-type transistor M2. In an example, a source of the p-type transistor M1 may be connected to the node N3 as the first power terminal of the inverter 152, and a source of the n-type transistor M2 may be connected to the node N4 as the second power terminal of the inverter 152. A drain of the p-type transistor M1 and a drain of the n-type transistor M2 may be the output terminal of the inverter 152, and a gate of the p-type transistor M1 and a gate of the n-type transistor M1 may be the input terminal of the inverter 152, and may be connected to a driver 140.

This charge pump circuit 150c may generate an output voltage V_OUT from an input voltage that repeats the power supply voltage V1 and the ground voltage according to the clock signal CLK.

Although the inverter 152 is shown in FIG. 5, in a non-limited example, the inverter 154 may also be configured in the same way as the inverter 152.

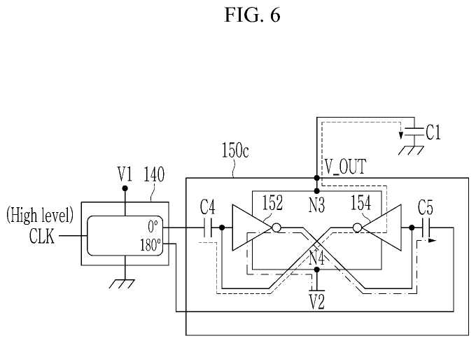

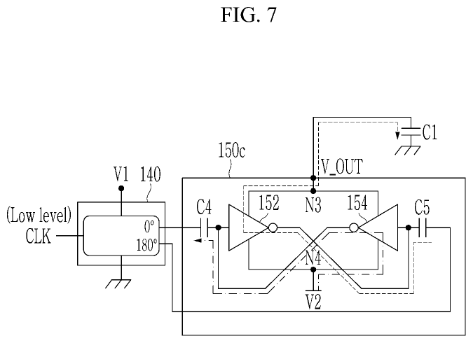

Then, with reference to FIGS. 6 and 7, a method for generating the output voltage V_OUT in the charge pump circuit 150c will be described.

FIG. 6 illustrates the operating state of the charge pump circuit shown in FIG. 5 in the first operation section, and FIG. 7 illustrates the operating state of the charge pump circuit shown in FIG. 5 in a second operation section.

Referring to FIG. 6, in the first operation period, the clock signal CLK may have a high level. A V1 voltage may be output to the non-inverting output terminal of the driver 140, and a 0V may be output to the inverting output terminal of the driver 140 according to the clock signal CLK having the high level. Accordingly, the n-type transistor of the inverter 152 may be turned on and the p-type transistor of the inverter 154 may be turned on. Then, the inverter 152 may output the V2 voltage and the pumping capacitor C5 may be charged with the V2 voltage. Furthermore, the pumping capacitor C4 may be charged with the V1 voltage, and the V1 voltage charged in the pumping capacitor C4 is transferred to the node N3 through the turned-on p-type transistor of the inverter 154, and the output capacitor C1 may be charged. At this time, the initial voltage charged to the output capacitor C1 may be higher than the V2 voltage and lower than the (V1+V2) voltage.

Next, referring to FIG. 7, the clock signal CLK may have a low level in the second operation period. The 0V may be output to the non-inverting output terminal of the driver 140, and a V1 voltage may be output to the inverting output terminal of the driver 140 according to the clock signal CLK having the low level. Accordingly, the p-type transistor of the inverter 152 may be turned on and the n-type transistor of the inverter 154 may be turned on. Then, the inverter 154 may output a voltage V2 and the pumping capacitor C4 may be charged with the (V2+V1) voltage. Furthermore, the pumping capacitor C5 may be charged with the (V2+V1) voltage. The (V2+V1) voltage charged in the pumping capacitor C5 may be transferred to the node N3 through the turned-on p-type transistor of the inverter 152 and the output capacitor C1 may be charged. At this time, the voltage charged to the output capacitor C1 may be higher than the V2 voltage and lower than the (V1+V2) voltage.

According to the clock signal CLK, the process shown in FIGS. 6 and 7 may be repeated, and the voltage charged in the output capacitor C1 may gradually increase, and finally the voltage of the output capacitor C1 may become (V1+V2) voltage. That is, the charge pump system 100 may output an output voltage V_OUT of (V1+V2) voltage, which is a positive voltage.

The clock signal CLK may be a clock signal CLK1 of the first oscillator 110 or a clock signal CLK2 of the second oscillator 120 depending on the voltage level of the control signal S_OSC.

According to one embodiment, when the output voltage V_OUT is less than the reference voltage V_REF, the clock signal CLK may be a clock signal of the first oscillator 110. When the output voltage V_OUT is greater than or equal to the reference voltage V_REF, the clock signal CLK may be a clock signal of the second oscillator 120.

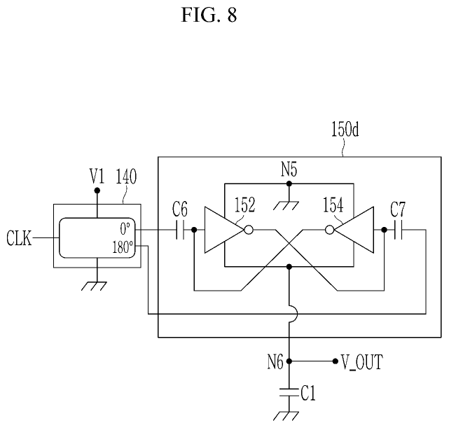

FIG. 8 is a diagram illustrating another example of the charge pump circuit shown in FIG. 1.

Referring to FIG. 8, the charge pump circuit 150d may include a pumping capacitor C6, a pumping capacitor C7, an inverter 152, and an inverter 154.

The driver 140 may have an input terminal, a non-inverting output terminal, and an inverting output terminal. The clock signal CLK may be input to the input terminal. The non-inverting output terminal may output the voltage selected according to the clock signal CLK. For example, the non-inverting output terminal may output a voltage V1 when the clock signal CLK has a high level and output 0V when the clock signal CLK has a low level. The inverting output terminal may output the phase-inverted voltage according to the clock signal CLK. For example, the inverting output terminal may output 0V when the clock signal CLK has a high level, and may output a voltage V1 when the clock signal CLK has a low level.

One end of the pumping capacitor C6 may be connected to the non-inverting output terminal of the driver 140, and the other end of the pumping capacitor C6 may be connected to an input terminal of the inverter 152.

One end of the pumping capacitor C7 may be connected to the inverting output terminal of the driver 140, and the other end of the pumping capacitor C7 may be connected to the input terminal of the inverter 154.

The inverter 152 may have an input terminal, an output terminal, a first power terminal, and a second power terminal. The output terminal of the inverter 152 may be connected to an input terminal of the inverter 154. The first power terminal of the inverter 152 may be connected to a node N5, and the second power terminal of the inverter 152 may be connected to a node N6.

The inverter 154 may have an input terminal, an output terminal, a first power terminal, and a second power terminal. The output terminal of the inverter 154 may be connected to the input terminal of the inverter 152. The first power terminal of the inverter 154 may be connected to the node N5, and the second power terminal of the inverter 154 may be connected to the node N6.

The node N5 may be connected to ground, the node N6 may be connected to output capacitor C1, and the voltage of node N6 may be the output voltage V_OUT of the charge pump circuit 150d.

In an example, the inverter 152 and the inverter 154 may be implemented as a combination of a p-type transistor M1 and an n-type transistor M2 as shown in FIG. 5.

This charge pump circuit 150d may generate an output voltage V_OUT from an input voltage that repeats the power supply voltage V1 and the ground voltage according to the clock signal CLK.

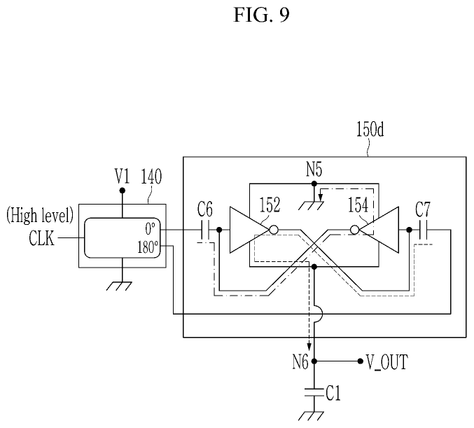

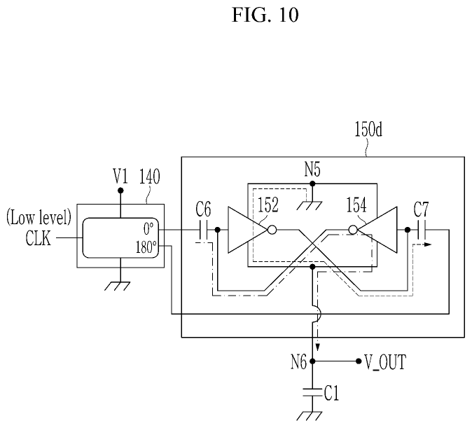

Then, with reference to FIGS. 9 and 10, a method for generating the output voltage V_OUT in the charge pump circuit 150d will be described.

FIG. 9 is a diagram showing the operating state of the charge pump circuit shown in FIG. 8 in the first operation section, and FIG. 10 is a diagram showing the operating state of the charge pump circuit shown in FIG. 8 in a second operation section.

Referring to FIG. 9, in the first operation period, the clock signal CLK may have a high level. A V1 voltage may be output to the non-inverting output terminal of the driver 140, and a 0V voltage may be output to the inverting output terminal of the driver 140 according to the clock signal CLK having a high level. Accordingly, the n-type transistor of the inverter 152 may be turned on and the p-type transistor of the inverter 154 may be turned on. Then, the pumping capacitor C6 may be charged with the voltage V1, and the 0V voltage may be applied to the pumping capacitor C7. The voltage of the pumping capacitor C7 is transferred to the node N6 through the turned-on n-type transistor of the inverter 152, and the output capacitor C1 may be charge. At this time, the voltage at the node N6 may gradually decrease due to the output capacitor C1 connected to ground.

Next, referring to FIG. 10, in the second operation period, the clock signal CLK may have a low level. A 0V voltage may be output to the non-inverting output terminal of the driver 140, and a V1 voltage may be output to the inverting output terminal of the driver 140 according to the clock signal CLK having the low level. Accordingly, the p-type transistor of the inverter 152 may be turned on and the n-type transistor of the inverter 154 may be turned on. Then, the 0V is applied to the pumping capacitor C6, and the −V1 voltage may be transferred to the node N6 through the turned-on n-type transistor of the inverter 154 by the voltage charged in the pumping capacitor C6, and the output capacitor C1 may be charged. At this time, the voltage at the node N6 may gradually decrease due to the output capacitor C1 connected to ground. The initial voltage charged to the output capacitor C1 may be lower than 0V and higher than −V1 voltage. Furthermore, the pumping capacitor C7 may be charged with the V1 voltage.

As the clock signal CLK may become high level again, the 0V may be applied to the pumping capacitor C7, and −V1 voltage may be transferred to the node N6 through the turned-on n-type transistor of the inverter 152 by the voltage charged in the pumping capacitor C7, and the output capacitor C1 may be charged. The voltage at the node N6 may gradually decrease to the −V1 voltage by the output capacitor C1 connected to ground.

According to the clock signal CLK, the process shown in FIGS. 9 and 10 may be repeated, and the voltage charged in the output capacitor C1 may gradually decrease, and finally the voltage of the output capacitor C1 may become −V1 voltage. That is, the charge pump system 100 may output an output voltage V_OUT of −V1 voltage, which is a negative voltage.

The clock signal CLK may be a clock signal CLK1 of the first oscillator 110 or a clock signal CLK2 of the second oscillator 120 depending on the voltage level of the control signal S_OSC.

According to one embodiment, when the output voltage V_OUT is less than the reference voltage V_REF, the clock signal CLK may be a clock signal of the first oscillator 110. When the output voltage V_OUT is greater than or equal to the reference voltage V_REF, the clock signal CLK may be a clock signal of the second oscillator 120.

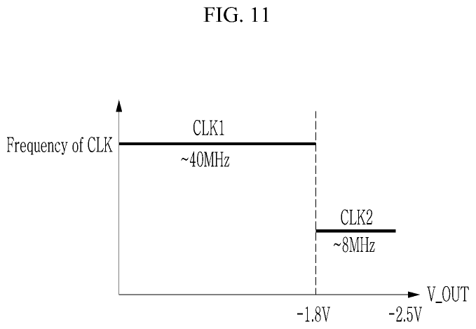

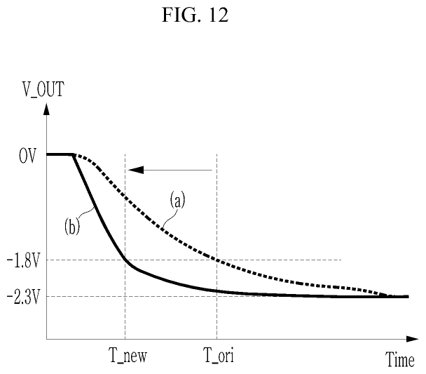

FIG. 11 is a diagram illustrating an example clock signal used in an example charge pump system, in according to one or more embodiments, and FIG. 12 is a graph showing the effect of the example charge pump system, in accordance with one or more embodiments.

In FIGS. 11 and 12, it was assumed that the charge pump circuit 150 of the charge pump system 100 generates a negative voltage of approximately −2.3V using a power supply voltage of 2.5V, and the reference voltage V_REF is −1.8V. The second oscillator 120 may provide a clock signal with a frequency of 8 MHz or less, and the first oscillator 110 may provide a clock signal with a frequency higher than the frequency provided by the second oscillator 120 and less than 40 MHz.

In FIG. 12, curve (a) may represent the output voltage V_OUT of the charge pump system that uses only the clock signal of the second oscillator 120 to avoid worsening the harmonic characteristics, and curve (b) may represent the output voltage V_OUT of the charge pump system 100 according to one embodiment.

Referring to FIG. 11, when the output voltage V_OUT of the charge pump circuit 150 is higher than −1.8V, the clock signal CLK1 of the first oscillator 110 may be used as the clock signal CLK, and when the output voltage V_OUT of the charge pump circuit 150 is lower than −1.8V, the clock signal CLK2 of the second oscillator 120 may be used as the clock signal CLK. That is, the clock signal CLK may be changed from the clock signal CLK1 of the first oscillator 110 to the clock signal CLK2 of the second oscillator 120 based on the reference voltage of −1.8V.

Referring to FIG. 12, upon initial startup, the charge pump system 100 operates using the clock signal CLK1 having a high frequency as the clock signal CLK according to comparison between the output voltage V_OUT and a reference voltage of −1.8V. As the charge pump system 100 operates using the clock signal CLK having the high frequency, the output voltage V_OUT may be quickly lowered. Then, when the output voltage V_OUT becomes less than or equal to the reference voltage V_REF, the clock signal CLK may be changed to the clock signal CLK2 having the low frequency, and the charge pump system 100 may operate using the clock signal CLK2 having the low frequency. Thus, the output voltage V_OUT may gradually decrease and may be maintained at −2.3V after reaching the target voltage of −2.3V.

As shown in FIG. 12, compared to the charge pump system that uses only the clock signal CLK2 of the second oscillator 120 to avoid worsening the harmonic characteristics, this charge pump system 100 according to one embodiment, may reduce the time to reach the reference voltage V_REF of −1.8V by (T_ori−T_new), and may reduce the time needed to reach the target voltage of −2.3V. In an example, T_ori may represent the time when the output voltage V_OUT of the charge pump system using only the clock signal of the second oscillator 120 reaches the reference voltage V_REF of −1.8V, and T_new may represent the time when the output voltage V_OUT of the charge pump system 100 according to one embodiment reaches the reference voltage V_REF of −1.8V. In other words, in the example of the charge pump system 100 according to one embodiment, the time needed to reach the target voltage upon initial startup may be reduced.

Additionally, the charge pump system 100 operates by a clock signal CLK having a low frequency after reaching the target voltage, thereby preventing deterioration of harmonic characteristics.

According to at least one of the embodiments, a high frequency clock signal may be used during initial startup, so the initial startup time may be shortened. Additionally, since a low frequency clock signal may be used when the output voltage reaches a predetermined reference voltage, harmonic characteristics may not deteriorate.

While specific examples have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A charge pump system, comprising:
a charge pump circuit configured to convert an input voltage to an output voltage;
a comparator configured to compare the output voltage with a reference voltage, and output a control signal that corresponds to a result of the comparing;
a driver configured to generate the input voltage in response to an operation clock signal, and provide the generated input voltage to the charge pump circuit; and
a selector configured to provide one of a first clock signal of a first frequency and a second clock signal of a second frequency lower than the first frequency as the operation clock signal to the driver, based on the control signal.

2. The charge pump system of claim 1, further comprising:
a first oscillator configured to generate the first clock signal and provide the generated first clock signal to the selector; and
a second oscillator configured to generate the second clock signal and provide the generated second clock signal to the selector.

3. The charge pump system of claim 2, wherein:
the second oscillator does not operate when the first oscillator operates, based on the control signal.

4. The charge pump system of claim 2, wherein:
the input voltage has a first voltage level and a second voltage level in response to the operation clock signal.

5. The charge pump system of claim 4, wherein:
the selector comprises a switch which has a first end that is connected to one of the first oscillator and the second oscillator based on the control signal, and a second end that is connected to the driver.

6. The charge pump system of claim 1, wherein:
the output voltage is a positive voltage,
the comparator is configured to output a control signal having a first level when the output voltage is lower than the reference voltage, and output a control signal having a second level when the output voltage is greater than or equal to the reference voltage, and
the selector is configured to provide a clock signal of the first frequency to the driver based on the control signal of the first level.

7. The charge pump system of claim 1, wherein:
the output voltage is a negative voltage,
the comparator is configured to output a control signal having a first level when the output voltage is greater than the reference voltage, and output a control signal having a second level when the output voltage is less than or equal to the reference voltage, and
the selector is configured to provide a clock signal of the first frequency to the driver based on the control signal of the first level.

8. A charge pump circuit operation method, comprising:
generating a first clock signal of a first frequency;
generating a second clock signal of a second frequency lower than the first frequency;
comparing an output voltage of the charge pump circuit with a reference voltage;
generating a control signal based on a result of the comparing;
selecting one of the first clock signal and the second clock signal in response to the control signal;
generating an input voltage of the charge pump circuit based on the selected clock signal; and
providing the generated input voltage to the charge pump circuit.

9. The operation method of claim 8, wherein:
the input voltage has a first voltage level and a second voltage level in response to the selected clock signal.

10. The operation method of claim 8, wherein:
the output voltage is a positive voltage,
the selecting of the one of the first clock signal and the second clock signal comprises:
selecting the first clock signal when the output voltage is lower than the reference voltage; and
selecting the second clock signal when the output voltage is greater than or equal to the reference voltage.

11. The operation method of claim 8, wherein:
the output voltage is a negative voltage,
the selecting of the one of the first clock signal and the second clock signal comprises:
selecting the first clock signal when the output voltage is greater than the reference voltage; and
selecting the second clock signal when the output voltage is less than or equal to the reference voltage.
